(19) United States
(12) Patent Application Publication
(10) Pub. No.: US 2009/0066242 A1
(43) Pub. Date: Mar. 12, 2009

(54) Display device

(75) Inventor: Hongmo Koo, Gumi-city (KR)

Correspondence Address: KED & ASSOCIATES, LLP, P.O. Box 221200, Chantilly, VA, 20153-1200, US

(73) Assignee: LG Electronics Inc.

(21) Appl. No.: 11/987,748

(22) Filed: Dec. 4, 2007

(30) Foreign Application Priority Data
Sep. 12, 2007 (KR) 10-2007-0092688

(51) Int. Cl. H01L 27/28

(52) U.S. Cl. 313/506

(57) ABSTRACT

A display device is provided that includes a first substrate, at least one inorganic insulating film on the first substrate, a light emitting unit on the first substrate (and including a first electrode, an organic film layer having a light emitting layer and a second electrode), a second substrate and a sealant for adhering the first substrate and the second substrate. A viscosity of the sealant may be approximately 80,000 cp to 150,000 cp.

This application claims priority under 35 U.S.C. §119(a) from Korean Patent Application No. 10-2007-0092688, filed Sep. 12, 2007, the entire subject matter of which is incorporated herein by reference.

### BACKGROUND

1. Field

Embodiments of the present invention may relate to a display device.

2. Background

Due to development of a multimedia, importance of display devices such as Flat Panel Displays (FPD) has been gradually increasing. Other displays such as a liquid crystal display (LCD), a Plasma Display Panel (PDP), a field emission display (FED), and an organic light emitting diode display are also being used.

An organic light emitting diode display may have a high response speed (of 1 ms or less), a low power consumption, and a self-luminance property. An organic light emitting diode display may also not have viewing problems. As such, organic light emitting diode displays may be considered future generation display devices.

The organic light emitting diode display is a display device for self-emitting in a light emitting layer that includes an organic matter that may be easily deteriorated by external moisture and oxygen. Therefore, the organic light emitting diode display may attempt to prevent the organic matter of the light emitting layer from being deteriorated. For example, the organic light emitting diode display may seal a first substrate and a second substrate by coating a sealant on the first substrate. When the sealant is provided along an outer edge of a light emitting unit, the sealant may have a straight portion and a curved portion.

Because a process specification of the curved portion of the sealant coated at an outer edge of the light emitting unit is not uniform, when the first substrate and the second substrate are cohered (or joined) together, the sealant may be pushed out or injected into the light emitting unit. This may reduce an area of the light emitting unit or may extend a bezel area at an outer edge of the panel.

Further, adhesive strength of the substrates may deteriorate or the sealant may be difficult to coat based on a viscosity of the sealant for adhering the first substrate and the second substrate.

### BRIEF DESCRIPTION OF THE DRAWINGS

Arrangements and embodiments may be described in detail with reference to the following drawings in which like reference numerals refer to like elements and wherein:

FIGS. 1A to 1C illustrate various arrangements of a color image display method in an organic light emitting device;

FIG. 2 is a plan view of a display device according to an example embodiment of the present invention;

FIG. 3 is a cross-sectional view taken along line I-I′ of FIG. 2;

FIGS. 4 and 5 are an enlarged views of area A of FIG. 2; and

FIG. 6 is a diagram illustrating an absorption rate in ultraviolet (UV) wavelengths of a photoinitiator of a sealant in an example embodiment of the present invention.

### DETAILED DESCRIPTION

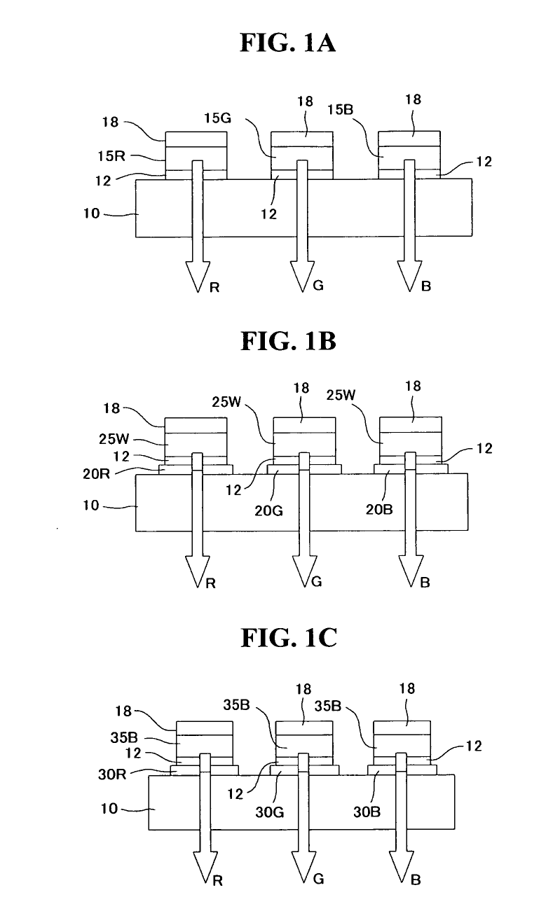

FIGS. 1A to 1C illustrate various implementations of a color image display method in an organic light emitting device. Other implementations may also be used. FIG. 1A illustrates a color image display method in an organic light emitting device that separately includes a red organic emitting layer 15R to emit red light, a green organic emitting layer 15G to emit green light and a blue organic emitting layer 15B to emit blue light. The red, green and blue light produced by the red, green and blue organic emitting layers 15R, 15G and 15B may be mixed to display a color image.

In FIG. 1A, the red, green and blue organic emitting layers 15R, 15G and 15B may each include an electron transport layer, an emitting layer, a hole transport layer, and the like. FIG. 1A also shows a substrate 10, an anode electrode 12 and a cathode electrode 18. Different dispositions and configurations of the substrate 10, the anode electrode 12 and the cathode electrode 18 may also be used.

FIG. 1B illustrates a color image display method in an organic light emitting device that includes a white organic emitting layer 25W to emit white light, a red color filter 20R, a green color filter 20G and a blue color filter 20B. And the organic light emitting device further may include a white color filter (not shown).

As shown in FIG. 1B, the red color filter 20R, the green color filter 20G and the blue color filter 20B each receive white light produced by the white organic emitting layer 25W and produce red light, green light and blue light, respectively. The red, green and blue light may be mixed to display a color image. In FIG. 1B, the white organic emitting layer 25W may include an electron transport layer, an emitting layer, a hole transport layer, and the like.

FIG. 1C illustrates a color image display method in an organic light emitting device that includes a blue organic emitting layer 35B to emit blue light, a red color change medium 30R, a green color change medium 30G and a blue color change medium 30B.

As shown in FIG. 1C, the red color change medium 30R, the green color change medium 30G and the blue color change medium 30B each receive blue light produced by the blue organic emitting layer 35B and produce red light, green light and blue light, respectively. The red, green and blue light may be mixed to display a color image. In FIG. 1C, the blue organic emitting layer 35B may include an electron transport layer, an emitting layer, a hole transport layer, and the like.

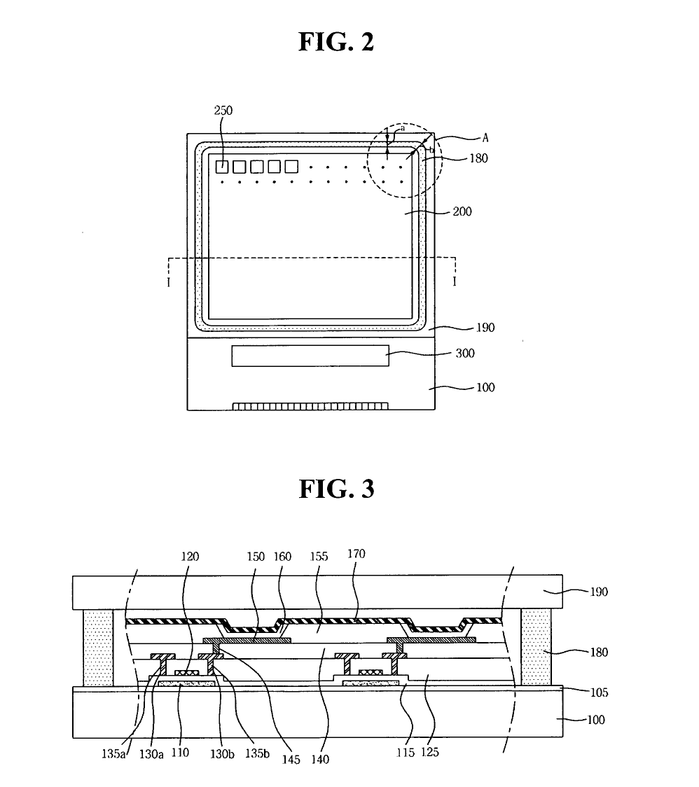

FIG. 2 is a plan view of a display device according to an example embodiment of the present invention. Other embodiments and configurations are also within the scope of the present invention.

More specifically, FIG. 2 shows a display device that includes a first substrate 100, a second substrate 190 opposite to the first substrate 100, a light emitting unit 200 positioned on the first substrate 100, a plurality of unit pixels 250 positioned within the light emitting unit 200, a sealant 180 positioned at an outer edge of the light emitting unit 200 to adhere the first substrate 100 and the second substrate 190, and a driver 300 for applying a signal to the light emitting unit 200.

The light emitting unit 200 may be positioned on the first substrate 100 and include an area for displaying an image. The light emitting unit 200 may include a plurality of unit pixels 250. Each unit pixel 250 may include 3 subpixels such as red (R), green (G), and blue (B) subpixels.

The driver 300 may apply a signal to the light emitting unit 200 and may be mounted as a Chip On Glass (COG) type of driver.

The sealant 180 for sealing the light emitting unit 200 by adhering the first substrate 100 and the second substrate 190 may be positioned at an outer edge of the light emitting unit 200. The sealant 180 may be positioned on the first substrate 100 to enclose an outer edge of the light emitting unit 200.

The sealant 180 may contact at least one inorganic insulating film formed on the first substrate 100, and the sealant 180 may contact the second substrate 190.

The sealant 180 may include a material for ultraviolet (UV) curing and may include an epoxy resin or an acryl resin as a major composition.

A viscosity of the sealant 180 may be approximately 80,000 cp to 150,000 cp in order to adhere the substrates 100 and 190. The viscosity of the sealant 180 may also be approximately 100,000 cp or 120,000 cp in order to adhere the substrates 100 and 190. The sealant 180 may be cured in an UV wavelength band, preferably 170 nm to 250 nm.

FIG. 3 is a cross-sectional view taken along line I-I′ of FIG. 2. FIG. 3 shows a buffer layer 105 positioned on the substrate 100. The buffer layer 105 may be formed to protect a thin film transistor (to be formed in a subsequent process) from impurities such as an alkali ion discharged from the substrate 100. The thin film transistor may be selectively formed using a silicone oxide (SiO2), a silicone nitride (SiNx), etc.

A semiconductor layer 110 may be positioned on the buffer layer 105. The semiconductor layer 110 may include amorphous silicon or polycrystalline silicon. The semiconductor layer 110 may include a channel area, a source area, and a drain area. P type impurities or N type impurities may be doped in the source area and the drain area.

A gate insulating film 115 may be positioned on the substrate 100 that includes the semiconductor layer 110. The gate insulating film 115 may be selectively formed using silicone oxide (SiO2) or a silicone nitride (SiNx).

A gate electrode 120 may be positioned on the gate insulating film 115 at a predetermined area (i.e., a channel area of the semiconductor layer 110). The gate electrode 120 may include any one of aluminum (Al), aluminum alloy (Al alloy), titanium (Ti), silver (Ag), molybdenum (Mo), molybdenum alloy (Mo alloy), tungsten (W), and tungsten silicide (WSi2). The gate electrode 120 may be formed of other materials.

An interlayer insulating film 125 may be positioned on the substrate 100 that includes the gate electrode 120. The interlayer insulating film 125 may be an organic film, an inorganic film, or a composite film of the organic film and the inorganic film.

When the interlayer insulating film 125 is an inorganic film, the interlayer insulating film 125 may include silicone oxide (SiO2), silicone nitride (SiNx), or silicate on glass (SOG). When the interlayer insulating film 125 is an organic film, the interlayer insulating film 125 may include an acryl resin, a polyimide resin, or a benzocyclobutene (BCB) resin. The interlayer insulating film 125 is not limited to the above materials.

Contact holes 13a and 130b may penetrate through the interlayer insulating film 125 and the gate insulating film 115 to expose part of the semiconductor layer 110.

A source electrode 135a and a drain electrode 135b may be electrically connected to the semiconductor layer 110 through the contact holes 130a and 130b. The source electrode 135a and the drain electrode 135b may each include a low resistance material in order to lower wiring resistance.

Further, a multilayer film may include moly tungsten (MoW), titanium (Ti), aluminum (Al), or aluminum alloy (Al alloy). The multilayer film may use a stacked structure of titanium/aluminum/titanium (Ti/Al/Ti), molybdenum/aluminum/molybdenum (Mo/Al/Mo), or moly tungsten/aluminum/moly tungsten (MoW/Al/MoW). The multilayer film is not limited to the above materials.

A planarization film 140 may be positioned on the source electrode 135a and the drain electrode 135b. The planarization film 140 may include an organic matter such as a benzocyclobutene (BCB) resin, an acryl resin, or a polyimide resin. The planarization film 140 is not limited to the above materials.

A first electrode 150 may be electrically connected to the drain electrode 135b through a via hole 145 formed in the planarization film 140. The first electrode 150 may be an anode and include a transparent conductive layer such as Indium Tin Oxide (ITO) or Indium Zinc Oxide (IZO). The first electrode 150 may also have a stacked structure that further includes a reflective film in a lower part of a transparent conductive layer. For example, the stacked structure may be ITO/Ag/ITO or ITO/Ag.

A bank layer 155 for exposing a partial area of the first electrode 150 may be positioned on the substrate 100 in which the first electrode 150 is formed. The bank layer 155 may include an organic matter such as a benzocyclobutene (BCB) resin, an acryl resin, or a polyimide resin. The bank layer 250 is not limited to the above materials.

An organic film layer 160 may be positioned on the first electrode 150 exposed by the bank layer 155. The organic film layer 160 may include at least a light emitting layer that includes an injection layer, an electron transport layer, a hole transport layer, and/or a hole injection layer in an upper part or a lower part of the light emitting layer.

At least one of the organic film layers 160 may further include inorganic matter having a metal compound. The metal compound may include an alkali metal or an alkaline earth metal, for example. The metal compound having the alkali metal or the alkaline earth metal may be one selected from a group consisting of LiF, NaF, KF, RbF, CsF, FrF, BeF2, MgF2, CaF2, SrF2, BaF2, and RaF2.

At least one of the organic film layers having an inorganic matter may perform a function of enabling a highest occupied molecular orbital level of an inorganic matter to lower a higher lowest unoccupied molecular orbital level of an organic matter constituting an organic film layer having an inorganic matter.

LiF may improve electron injection characteristics to the light emitting layer by forming a strong dipole, thereby improving light emitting efficiency and lowering a driving voltage.

Therefore, an inorganic matter within at least one organic film layer having an inorganic matter facilitates hopping of electrons injected from the second electrode into the light emitting layer, thereby adjusting a balance of holes and electrons injected into the light emitting layer and thereby improving light emitting efficiency.

A second electrode 170 may be positioned on the substrate 100 that includes the organic film layer 160. The second electrode 170 may be a cathode for supplying electrons to the light emitting layer. The second electrode 170 may include magnesium (Mg), silver (Ag), calcium (Ca), aluminum (Al), and/or alloys thereof.

The first substrate 100 and the second substrate 190 may be adhered together by the sealant 180 to seal the light emitting unit 200.

The sealant 180 may directly contact an inorganic insulating film positioned on the first substrate 100. For example, the sealant 180 may contact the buffer layer 105, which is an inorganic insulating film. Alternatively, the sealant 180 may contact a gate insulating film or an interlayer insulating film.

The sealant 180 may contact an inorganic insulating film such as a buffer layer, a gate insulating film, or an interlayer insulating film, thereby improving adhesion characteristics between the sealant 180 and the first substrate 100.

The sealant 180 may include a material for UV curing and an epoxy resin or an acryl resin as a major composition. The sealant may further include a photoinitiator for generating a polymerization reaction by absorbing UV energy when UV is radiated. The photoinitiator may be 1 to 5 wt % of a total sealant.

A viscosity of the sealant 180 may be approximately 80,000 cp to 150,000 cp in order to adhere the substrates 100 and 190. The viscosity of the sealant 180 may also be approximately 100,000 cp or 120,000 cp in order to adhere the substrates 100 and 190.

If a viscosity of the sealant 180 is 80,000 cp or more, then when a process of coating the sealant 180 is performed using a dispensing method, a line width of the sealant 180 may be prevented from being formed to be wider than a width in the process specification. Accordingly, a problem of a scribing process due to a widened line width of the sealant 180 after cohesion of the substrates may be avoided or minimized. Still further, a problem that an area of a light emitting unit may be reduced due to a sealant penetrated into the light emitting unit can be avoided and/or minimized.

Further, if a viscosity of the sealant 180 is 150,000 cp or lower (due to a high viscosity of the sealant), then when an application process of the sealant 180 is performed using a dispensing method, problems of being difficult to push the sealant out from a dispenser with air pressure can be avoided and/or minimized.

Therefore, the display device may improve adhesive strength of the sealant and may prevent a decrease of an area of the light emitting unit by using the sealant having a viscosity of approximately 80,000 cp to 150,000 cp on an inorganic insulating film formed on the first substrate.

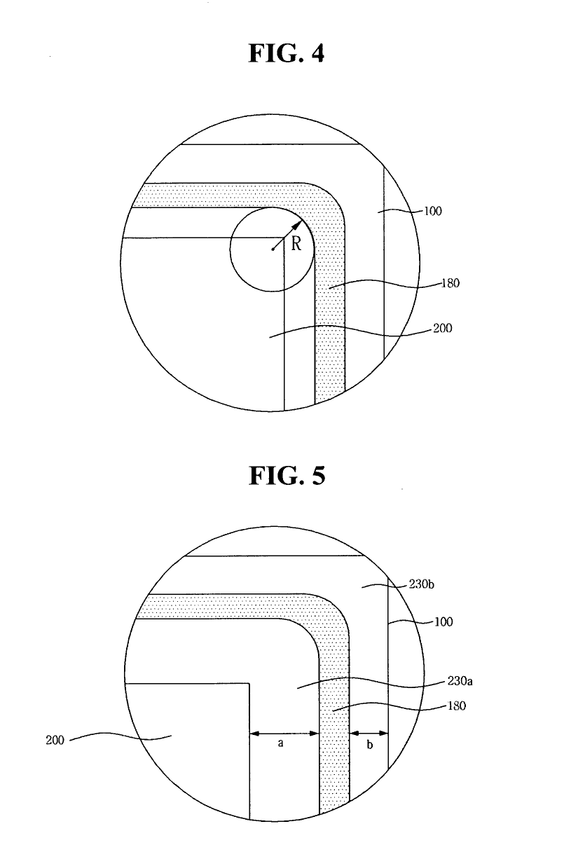

FIG. 4 is an enlarged view of an area A of FIG. 2. As shown in FIG. 4, the light emitting unit 200 may be positioned on the first substrate 100. The light emitting unit 200 may include a first electrode, an organic film layer having a light emitting layer, and a second electrode. The light emitting unit may further include a thin film transistor having a semiconductor layer, a gate electrode, a source electrode, and a drain electrode.

The sealant 180 may seal the light emitting unit 200. The sealant 180 may use a material for UV curing, and may include an epoxy resin or an acryl resin as a major composition. The sealant 180 may further include a photoinitiator for generating a polymerization reaction by absorbing UV energy when UV is radiated. The photoinitiator may be 1 to 5 wt % of a total sealant.

A viscosity of the sealant 180 may be 80,000 cp to 150,000 cp in order to adhere the substrates 100 and 190. The viscosity of the sealant 180 may be approximately 100,000 cp or 120,000 cp in order to adhere the substrates 100 and 190.

If a viscosity of the sealant 180 is 80,000 cp or more, then when a process of coating the sealant 180 is performed using a dispensing method, a line width of the sealant 180 may be prevented from being formed to be wider than a width in a process specification. Thus, a problem of a scribing process due to a widened line width of the sealant 180 after cohesion of the substrates may be solved and/or minimized. Additionally, a problem of an area of a light emitting unit being reduced due to a sealant penetrated into the light emitting unit may be solved and/or minimized.

Further, if a viscosity of the sealant 180 is 150,000 cp or lower (due to a high viscosity of the sealant), then when an application process of the sealant is performed using a dispensing method, problems of being difficult to push the sealant out from a dispenser with air pressure can be avoided and/or minimized.

As shown in FIG. 4, the sealant 180 may include a straight portion coated in a straight line at an outer edge of the light emitting unit 200, and a curved portion coated in a curved line at a corner portion of the light emitting unit 200.

According to an example embodiment of the present invention, a ratio of a width of the straight portion to a width of the curved portion of the sealant 180 may be 1:1 to 1:1.5. If a ratio of a width of the straight portion to a width of the curved portion is 1:1 or more, then a width of the curved portion of the sealant 180 may become narrow so that adhesive strength of the curved portion can be prevented from being deteriorated and a process condition of controlling a discharge amount of the sealant can be easily secured.

If a ratio of a width of the straight portion to a width of the straight portion of the sealant 180 is 1:1.5 or less, then due to increase of a width of the curved portion of the sealant 180, a problem of an increased bezel area of the panel may be solved and/or minimized and a problem of a panel size increasing can be solved and/or minimized.

Further, the curved portion of the sealant 180 may be formed to have a radius of curvature (R) of 0.2 mm to 2.5 mm. If the radius of curvature (R) of the curved portion of the sealant 180 is 0.2 mm or more, then after the sealant 180 is applied a push-out amount of the sealant 180 may be easily controlled when the substrates 100 and 190 are cohered, and a difficult panel scribing problem due to pushed-out sealant can be solved and/or minimized.

If a radius of curvature (R) of the curved portion of the sealant 180 is 2.5 mm or less, then a radius of curvature (R) of the curved portion of the sealant 180 may increase so that an increase of the bezel area or a decrease of an area of the light emitting unit can be prevented and/or minimized.

By forming a radius of curvature (R) of the curved portion of the sealant 180 (having a viscosity of 80,000 cp to 150,000 cp) to 0.2 mm to 2.5 mm, an increase of the bezel area or a decrease of an area of the light emitting unit can be prevented and/or minimized.

FIG. 5 is an enlarged view of the area A of FIG. 2. As discussed above, the light emitting unit 200 may be positioned on the first substrate 100. The light emitting unit 200 may include a first electrode, an organic film layer (having at least a light emitting layer) and a second electrode. The light emitting unit 200 may further include a thin film transistor having a semiconductor layer, a gate electrode, a source electrode, and a drain electrode.

As shown in FIG. 5, inside and outside bezel areas 230a and 230b are provided on the first substrate 100. The bezel areas may be considered to be at an outer edge of the light emitting unit 200 and/or about (or around) the light emitting unit. The sealant 180 for sealing the light emitting unit 200 positioned on the first substrate 100 may be on the inside and outside bezel areas 230a and 230b and/or may be provided at an area between the inside bezel area 230a and the outside bezel area 230b. The outside bezel area 230b may be provided outside the sealant 180 (i.e., outside from the light emitting unit 200), and the inside bezel area 230a may be considered inside the sealant 180 (i.e., adjacent the light emitting unit 200).

The sealant 180 may use a material for UV curing, and may include an epoxy resin or an acryl resin as a major composition. The sealant 180 may further include a photoinitiator for generating a polymerization reaction by absorbing UV energy when UV is radiated. The photoinitiator may be 1 to 5 wt % of a total sealant.

A viscosity of the sealant 180 may be approximately 80,000 cp to 150,000 cp in order to adhere the substrates 100 and 190. The viscosity of the sealant 180 may be approximately 100,000 cp or 120,000 cp in order to adhere the substrates 100 and 190.

If a viscosity of the sealant 180 is 80,000 cp or more, then when a process of coating the sealant 180 is performed using a dispensing method, a line width of the sealant 180 may be prevented from being formed to be wider than a width in a process specification. Accordingly, a problem of a scribing process due to a widened line width of the sealant after cohesion of the substrates may be avoided and/or minimized. Still further, a problem that an area of a light emitting unit may be reduced due to a sealant penetrated into the light emitting unit may be avoided and/or minimized.

Further, if a viscosity of the sealant 180 is 150,000 cp or lower (due to a high viscosity of the sealant), then when an application process of the sealant 180 is performed using a dispensing method, problems of being difficult to push the sealant 180 out from a dispenser with air pressure may be avoided and/or minimized.

The bezel area may be divided into the inside bezel area 230a and the outside bezel area 230b by the sealant 180. That is, an area of the light emitting unit 200 becomes the inside bezel area 230a based on the sealant 180, and an area of the first substrate 100 becomes the outside bezel area 230b based on the sealant. The outside bezel area 230b and the inside bezel area 230a may be divided by the sealant 180 in a ratio of 1:1.5.

When the sealant 180 is selected as a sealing material in a sealing process, upon cohering the first substrate 100 and the second substrate (not shown), the sealant 180 may extend to left and right sides toward the inside bezel area 230a and the outside bezel area 230b, respectively (as shown with respect to FIG. 5).

A width (a) of the inside bezel area 230a may be greater than a width (b) of the outside bezel area 230b in order to prevent (or minimize) the sealant 180 from being injected into the light emitting unit 200. This may also minimize a harmful influence on an element within the light emitting unit 200 when UV is radiated in order to cure the sealant 180 in a sealing process.

When a sealant dispenser is used, a ratio of the outside bezel area 230b and the inside bezel area 230a may be described by a numerical value as follows. The width (b) of the outside bezel area 230b may have a range of approximately 200 μm from an outer edge of the sealant 180 and the width (a) of the inside bezel area 230a may have a range of 300 μm from the sealant 180, and an error range of the inside bezel area 230a and the outside bezel area 230b may be ±2%. The error range of ±2% may be set in consideration of a process margin that may be generated when each bezel area is formed.

As one example, the width (b) of the outside bezel area 230b may be approximately 196 μm to 204 μm as measured from an outer edge of the sealant 180, and the width (a) of the inside bezel area 230a may be approximately 294 μm to 306 μm as measured from an inner edge of the sealant 180.

Therefore, by forming a sealant having a viscosity of 80,000 cp to 150,000 cp in a bezel area so that a ratio of widths of the outside bezel area 230b and the inside bezel area 230a is 1:1.5, a reduction phenomenon of the light emitting unit can be prevented and/or minimized and reliability of a process may be improved.

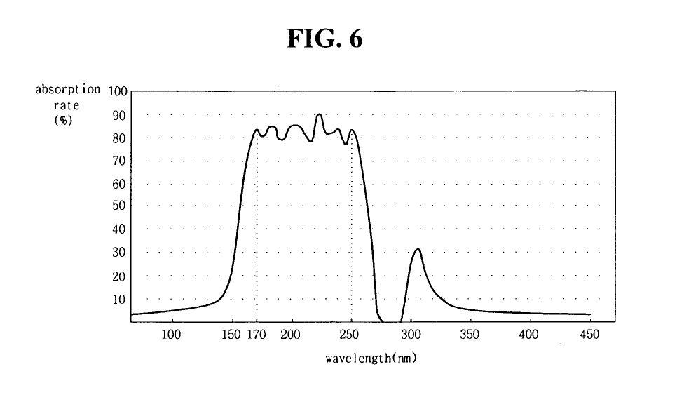

FIG. 6 is a diagram illustrating an absorption rate in UV wavelengths of a photoinitiator of a sealant according to an example embodiment of the present invention. Other embodiments are also within the scope of the present invention. In FIG. 6, an abscissa of a graph represents a wavelength and an ordinate of the graph represents an absorption rate of a photoinitiator.

As shown in FIG. 6, the sealant 180 may be cured in an UV wavelength band, preferably 170 nm to 250 nm. That is, the photoinitiator of the sealant may have an UV absorption rate of 85% or more in a wavelength of 170 nm to 250 nm.

The photoinitiator added to the sealant 180 may enable UV to be more easily absorbed in an UV wavelength band of 170 nm to 250 nm. In more detail, as UV is applied, a polymerization reaction of the photoinitiator may be performed. However, a polymerization reaction may be actively performed from a wavelength of approximately 170 nm and thus actual curing of the sealant may start. An UV absorption rate of the photoinitiator may be high including up to a wavelength of approximately 250 nm. However, in a wavelength of more than 250 nm, an UV absorption rate of the photoinitiator may rapidly deteriorate and curing may not be substantially performed.

The sealant 180 may perform substantial curing in a wavelength range of 170 nm to 250 nm.

The display device having the above configuration may include a sealant having a radius of curvature (R) of 0.2 mm to 2.5 mm and a viscosity of approximately 80,000 cp to 150,000 cp so that push-out of the sealant to outside of a coated area can be prevented, and/or an increase of the bezel area or decrease of an area of the light emitting unit may be prevented.

Further, by directly contacting a sealant with an inorganic insulating film excellent in adhesion characteristics with the sealant, a peeling phenomenon of the sealant may be prevented and/or minimized and adhesive strength of substrates can be improved.

Additionally, by forming a sealant having a viscosity of approximately 80,000 cp to 150,000 cp in a bezel area so that a ratio of an outside area and an inside area is 1:1.5, a reduction phenomenon of the light emitting unit may be prevented and/or minimized and reliability of a process can be improved.

The above described embodiments describe the light emitting unit 200. The light emitting unit 200 may include a plurality of unit pixels with each unit pixel including a plurality of subpixels. For example, FIGS. 1A-1C show different arrangements of red, blue, green and white light emitting layers to produce various combinations of red, blue and green light. Other combinations and/or colors may be used. The light emitting layers of the subpixels may include phosphorescence material and/or fluorescence material. The arrangements of FIGS. 1A-1C may be provided within any of the embodiments of the present invention and/or displays associated with each of FIGS. 2-6.

In an example where the subpixel emits red light, the emitting layer of the subpixel may include a host material including carbazole biphenyl (CBP) or 1,3-bis(carbazol-9-yl (mCP), and may be formed of a phosphorescence material including a dopant material including PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum) or a fluorescence material including PBD:Eu(DBM)3(Phen) or Perylene.

In an example where the subpixel emits green light, the emitting layer may include a host material including CBP or mCP, and may be formed of a phosphorescence material including a dopant material including Ir(ppy)3(fac tris(2-phenylpyridine)iridium) or a fluorescence material including Alq3(tris(8-hydroxyquinolino)aluminum).

In an example where the subpixel emits blue light, the emitting layer may includes a host material including CBP or mCP, and may be formed of a phosphorescence material including a dopant material including (4,6-F2ppy)2Irpic or a fluorescence material including spiro-DPVBi, spiro-6P, distyryl-benzene (DSB), distyryl-arylene (DSA), PFO-based polymers, PPV-based polymers, or a combination thereof.

Embodiments of the present invention may provide a display device that can improve reliability.

Embodiments of the present invention may provide a display device that includes a first substrate, at least one inorganic insulating film positioned on the first substrate, a light emitting unit positioned on the first substrate (and including a first electrode, an organic film layer (including a light emitting layer) and a second electrode), a second substrate for sealing the light emitting unit, and a sealant for adhering the first substrate and the second substrate. The sealant may contact the inorganic insulating film. A viscosity of the sealant may be approximately 80,000 cp to 150,000 cp.

Embodiments of the present invention may also provide a display device that includes a first substrate, a light emitting unit positioned on the first substrate (and including a first electrode, an organic film layer (including a light emitting layer) and a second electrode), a second substrate for sealing the light emitting unit, and a sealant for adhering the first substrate and the second substrate. The sealant may include a straight portion and a curved portion. A ratio of a width of the straight portion to a width of the curved portion of the sealant may be approximately 1:1 to 1:1.5. A viscosity of the sealant may be approximately 80,000 cp to 150,000 cp.

Additionally, embodiments of the present invention may also provide a display device that includes a first substrate, a light emitting unit positioned on the first substrate (and including a first electrode, an organic film layer (including a light emitting layer) and a second electrode), a bezel area positioned at an outer edge of the light emitting unit, a second substrate for sealing the light emitting unit, and a sealant positioned on the bezel area for adhering the first substrate and the second substrate. The viscosity of the sealant may be approximately 80,000 cp to 150,000 cp. The bezel area may include an outside area and an inside area based on the sealant. A ratio of a width of an outside area to a width of the inside area may be approximately 1:1.5.

Embodiments of the present invention may provide a display device that includes a first substrate, a thin film transistor positioned on the first substrate (including a semiconductor layer, a gate insulating film, a gate electrode, an interlayer insulating film, a source electrode and a drain electrode), at least one inorganic insulating film positioned on the first substrate, a light emitting unit positioned on the first substrate (and including a first electrode, an organic film layer having a light emitting layer, and a second electrode), a second substrate for sealing the light emitting unit, and a sealant for adhering the first substrate and the second substrate and contacting the inorganic insulating film. The sealant may include a straight portion and a curved portion. A viscosity of the sealant may be approximately 80,000 cp to 150,000 cp. A radius of curvature (R) of the curved portion of the sealant may be approximately 0.2 mm to 2.5 mm.

A difference between driving voltages, e.g., the power voltages VDD and Vss of the organic light emitting device may change depending on the size of the display panel 100 and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) of | | | |
|---|---|---|---|
| display panel | VDD-Vss (R) | VDD-Vss (G) | VDD-Vss (B) |
| S < 3 inches | 3.5-10 (V) | 3.5-10 (V) | 3.5-12 (V) |
| 3 inches < S < 20 | 5-15 (V) | 5-15 (V) | 5-20 (V) |
| inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

The display device having the above-described structure may be encapsulated with the second substrate using a sealing material such as a frit or a sealant.

An organic layer has generally a water vapor permeation rate of 100 g/m2/day, and an inorganic layer has generally a water vapor permeation rate of 10-1 g/m2/day.

A display device has generally a water vapor permeation rate of 10-2 g/m2/day. The display device according to the exemplary embodiment uses a sealing material having a water vapor permeation rate more than 10-3 g/m2/day and an oxygen vapor permeation rate more than 10-6 g/m2/day, and thus can have excellent moisture and oxygen prevention properties.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A display device comprising:
a first substrate;
a light emitting unit on the first substrate, the light emitting unit including a first electrode, an organic film layer having a light emitting layer and a second electrode;
a second substrate on the light emitting unit; and
a sealant to adhere the first substrate to the second substrate,
wherein a viscosity of the sealant is approximately 80,000 cp to 150,000 cp.

2. The display device of claim 1, further comprising:
at least one inorganic insulating film on the first substrate, wherein the sealant contacts the inorganic insulating film on the first substrate.

3. The display device of claim 2, wherein the inorganic insulating film comprises a buffer layer, a gate insulating film or an interlayer insulating film.

4. The display device of claim 1, wherein the viscosity of the sealant is approximately 100,000 cp to 120,000 cp.

5. The display device of claim 1, further comprising a thin film transistor including a semiconductor layer, a gate insulating film, a gate electrode, an interlayer insulating film, a source electrode and a drain electrode on the first substrate.

6. The display device of claim 1, wherein the sealant is cured at a wavelength of approximately 170 nm to 250 nm.

7. The display device of claim 1, wherein the sealant is provided at an area outside of the light emitting unit.

8. The display device of claim 1, wherein the sealant comprises an epoxy resin or an acrylic resin.

9. The display device of claim 1, wherein the first electrode comprises a transparent conductive layer having a reflective film in a part of the transparent conductive layer.

10. The display device of claim 1, wherein the light emitting unit includes a plurality of subpixels, and at least one subpixel includes a white light emitting layer.

11. The display device of claim 1, wherein the light emitting unit includes a plurality of subpixels, and at least one subpixel includes an emitting layer having a phosphorescence material.

12. A display device comprising:
a first substrate;
a light emitting unit on the first substrate, the light emitting unit including a first electrode, an organic film layer having a light emitting layer and a second electrode;
a second substrate on the light emitting unit; and
a sealant provided about the light emitting unit in a straight portion and a curved portion, the sealant to adhere the first substrate to the second substrate,
wherein a ratio of a width of the straight portion to a width of the curved portion is approximately 1:1 to 1:1.5, and a viscosity of the sealant is approximately 80,000 cp to 150,000 cp.

13. The display device of claim 12, wherein the viscosity of the sealant is approximately 100,000 cp to 120,000 cp.

14. The display device of claim 12, further comprising a thin film transistor including a semiconductor layer, a gate insulating film, a gate electrode, an interlayer insulating film, a source electrode and a drain electrode on the first substrate.

15. The display device of claim 12, wherein the sealant is cured at a wavelength of approximately 170 nm to 250 nm.

16. The display device of claim 12, wherein the sealant comprises an epoxy resin or an acrylic resin.

17. The display device of claim 12, wherein the first electrode comprises a transparent conductive layer and a reflective film in a part of the transparent conductive layer.

18. A display device comprising:
a first substrate;
a light emitting unit on the first substrate, the light emitting unit including a first electrode, an organic film layer having a light emitting layer and a second electrode;
a bezel area about the light emitting unit;
a second substrate on the light emitting unit; and
a sealant to adhere the first substrate to the second substrate,
wherein the bezel area includes a first bezel area outside the sealant and a second bezel area inside the sealant, wherein a ratio of a width of the first bezel area to a width of the second bezel area is approximately 1:1.5, and wherein a viscosity of the sealant is approximately 80,000 cp to 150,000 cp.

19. The display device of claim 18, wherein the viscosity of the sealant is approximately 100,000 cp to 120,000 cp.

20. The display device of claim 18, wherein the width of the first bezel area is approximately 196 μm to 204 μm as measured from an outer edge of the sealant, and the width of the second bezel area is approximately 294 μm to 306 μm as measured from an inner edge of the sealant.

21. The display device of claim 18, further comprising a thin film transistor including a semiconductor layer, a gate insulating film, a gate electrode, an interlayer insulating film, a source electrode and a drain electrode on the first substrate.

22. The display device of claim 18, wherein the sealant is cured at a wavelength of approximately 170 nm to 250 nm.

23. The display device of claim 18, wherein the sealant includes an epoxy resin or an acrylic resin.

24. A display device comprising:
a first substrate;
a thin film transistor on the first substrate, the thin film including a semiconductor layer, a gate insulating film, a gate electrode, an interlayer insulating film, a source electrode and a drain electrode;
a light emitting unit on the first substrate, the light emitting unit including a first electrode, an organic film layer having a light emitting layer and a second electrode;
a second substrate to cover the light emitting unit; and
a sealant provided between the first substrate and the second substrate in a straight portion and a curved portion, wherein a radius of curvature of the curved portion is approximately 0.2 mm to 2.5 mm, and wherein a viscosity of the sealant is approximately 80,000 cp to 150,000 cp.

25. The display device of claim 24, wherein the viscosity of the sealant is approximately 100,000 cp to 120,000 cp.
